(19) United States
(12) Patent Application Publication
(10) Pub. No.: US 2008/0182008 A1
(43) Pub. Date: Jul. 31, 2008

(54) Apparatus and method for coating and inspecting objects

(76) Inventors: Gerald F. Snow, Almont, MI (US); James Patrick DeFillipi, Leonard, MI (US)

Correspondence Address: BLISS MCGLYNN, P.C., 2075 WEST BIG BEAVER ROAD, SUITE 600, TROY, MI, 48084, US

(21) Appl. No.: 11/700,601

(22) Filed: Jan. 31, 2007

(51) Int. Cl. C23C 16/52; G01N 21/00

(52) U.S. Cl. 427/8; 356/237.1

(57) ABSTRACT

An apparatus and method for inspecting objects for an inspection criteria thereon includes a conveyor to receive a plurality of objects, a removal assembly located along the conveyor for removing the objects, and an inspection system located along the conveyor prior to the removal assembly for inspecting the objects against a predetermined inspection criteria to determine to reject or pass the inspected objects and to actuate said removal assembly to a passed position if the inspected objects are passed and to leave said removal assembly in a failed position if the inspected objects are rejected.

### BACKGROUND OF THE INVENTION

1. Field of the Invention

The present invention relates generally to inspection of objects and, more specifically, to an apparatus and method for coating and inspecting an inspection criteria on objects such as fasteners.

2. Description of the Related Art

It is known to apply a coating to objects such as fasteners with automated machinery. Once the coating is applied, the fasteners are inspected to determine if the coating or an additional attribute(s) such as thread pitch, thread diameter, thread length, fastener head style, or head marking of the fastener was sufficient to meet predetermined inspection criteria. For example, the fasteners are inspected to determine if the coating covers a predetermined area of the fasteners. This inspection of the coated fasteners is needed for processing quality control.

One method of inspecting the fasteners is to manually and visually inspect the fasteners. This may be performed randomly or in entirety. However, this inspection method is laborious and time consuming. Manual inspection requires the presence of an operator, limits processing speed, and is also dependent on variable parameters such as operator fatigue.

Another method of inspecting the fasteners is to use a machine vision system for automatically and continuously monitoring and controlling the processing of fasteners. An example of such a method is disclosed in U.S. Pat. No. 6,620,246 to Alaimo et al. In this patent, a process controller enables automatic and sequential start-up and shut-down of one or more fastener coating machines and/or subsystems for each machine. The process controller includes a fiber optic light source, a programmable logic controller, and a camera controller. A dial machine for coating internally threaded fasteners includes various ejector tubes for accommodating fasteners and may include a “purge” ejector tube for conveying fasteners or parts to a recycling location, a “defective parts” ejector tube for conveying fasteners to a defective parts bin, and a “good parts” ejector tube for conveying properly coated fasteners to a cooling location. Fasteners may be selectively ejected from a turntable track using bursts of compressed air from tubes. A camera housing is provided for conveying video images to the process controller. A suitable machine vision system may be used with the process controller.

Therefore, it is desirable to provide an apparatus to coat objects and then to inspect objects such as fasteners for process quality control. It is also desirable to provide an apparatus to automatically inspect coated fasteners after the coating process and additional attributes of the fasteners. It is further desirable to provide an apparatus and methodology in which passed objects from inspection flow to a good part removal and are removed and rejected objects from inspection flow to a default part removal and removed. Thus, there is a need in the art to provide an apparatus and methodology that meets at least one of these desires.

### SUMMARY OF THE INVENTION

It is, therefore, one object of the present invention to provide an apparatus and method for inspecting objects for process quality control.

It is another object of the present invention to provide an apparatus and method that automatically inspects objects.

It is yet another object of the present invention is to provide an apparatus and method to inspect coated fasteners and additional attributes of the fasteners.

To achieve one or more of the foregoing objects, the present invention is an apparatus for inspecting objects for an inspection criteria thereon. The apparatus includes a conveyor to receive a plurality of objects and a removal assembly located along the conveyor for removing the objects. The apparatus also includes an inspection system located along the conveyor prior to the removal assembly for inspecting the objects against a predetermined inspection criteria to determine to reject or pass the inspected objects and to actuate the removal assembly to a passed position if the inspected objects are passed and to leave the removal assembly in a failed position if the inspected objects are rejected.

Also, the present invention is a method for inspecting objects for an inspection criteria thereon. The method includes the steps of providing a conveyor, receiving a plurality of objects on the conveyor, and conveying the objects along the conveyor. The method also includes the steps of inspecting the objects with an inspection system located along the conveyor against a predetermined inspection criteria, determining to reject or pass the inspected objects, removing the passed objects from the conveyor with a removal assembly by actuating the removal assembly to a passed position if the inspected objects are passed, and removing the rejected objects from the conveyor with the removal assembly in a failed position if the inspected objects are rejected, or as a result of a system malfunction “default object removal”.

One advantage of the present invention is that an apparatus and method is provided for inspecting a flow of objects such as fasteners in an ordinate and incremental position at a high rate of speed. Another advantage of the present invention is that the an inspection methodology is provided in which passed objects from inspection flow to a good object removal and are removed and rejected objects from inspection flow to a default object removal and are removed. Yet another advantage of the present invention is that the apparatus and method automatically inspects coated objects such as fasteners and additional attributes of the fasteners after the coating process.

Other objects, features, and advantages of the present invention will be readily appreciated, as the same becomes better understood, after reading the subsequent description taken in conjunction with the accompanying drawings.

### BRIEF DESCRIPTION OF THE DRAWINGS

FIG. 1 is a front elevational view of an apparatus, according to the present invention.

FIG. 2 is a side elevational view of the apparatus of FIG. 1.

FIG. 3 is a side elevational view of a portion of the apparatus of FIG. 1.

FIGS. 4A and 4B are a flowchart of a method, according to the present invention, of inspecting objects using the apparatus of FIG. 1.

### DESCRIPTION OF THE PREFERRED EMBODIMENT(S)

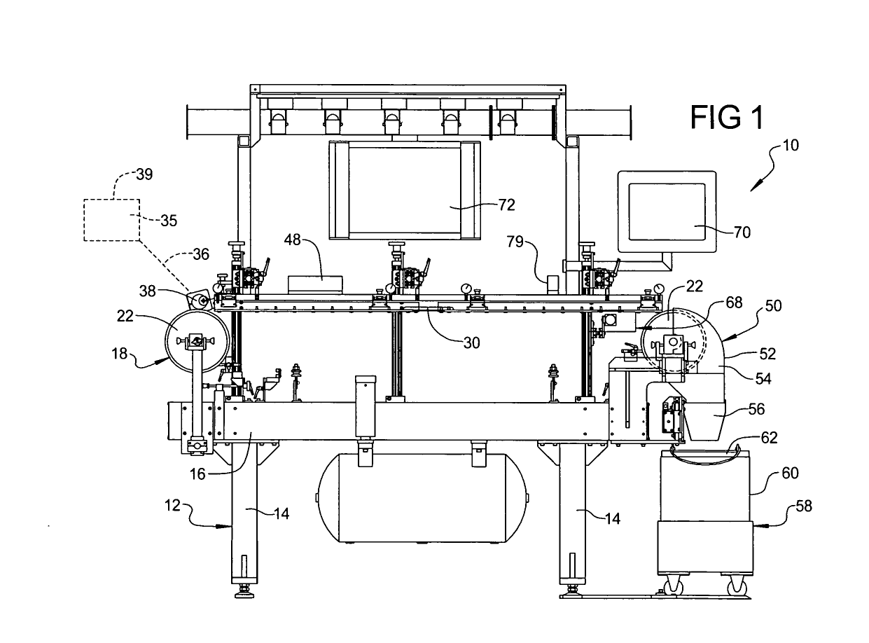

Referring now to the drawings, and in particular FIG. 1, one embodiment of an apparatus 10, according to the present invention, is shown. The apparatus 10 includes a support frame, generally indicated at 12. The support frame 12 includes at least one, preferably a plurality of columns 14 and at least one, preferably a plurality of beams 16 connected together by a suitable mechanism such as brackets and fasteners.

The apparatus 10 also includes a conveyor system, generally indicated at 18, for conveying objects such as fasteners. The objects such as fasteners each have a diameter of approximately 0.020 inches to approximately 1.50 inches and a length of approximately 0.030 inches to approximately 10.00 inches. In one embodiment, the objects are fasteners of a M1 type. It should be appreciated that the objects may be of a type other than fasteners.

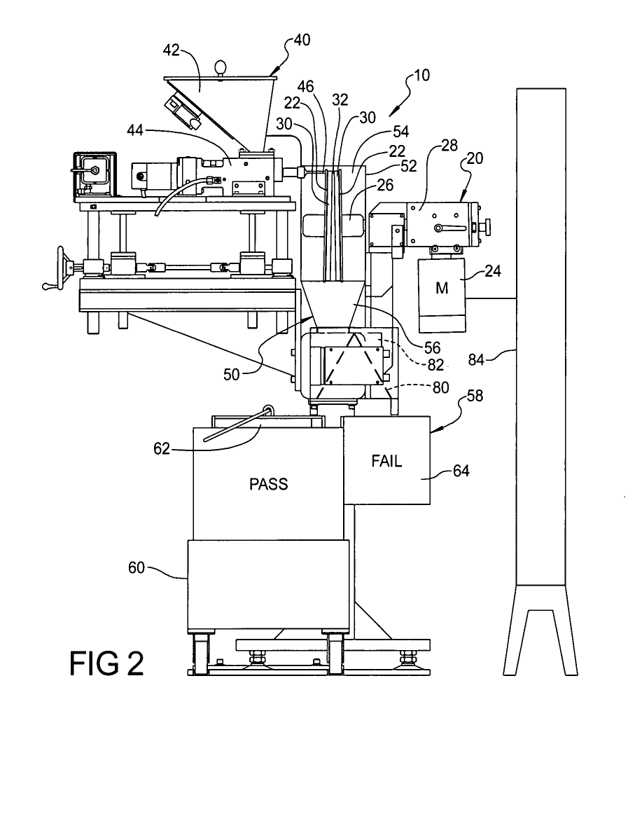

The conveyor system 18 is of a dual or split belt type. The conveyor system 18 includes a drive system, generally indicated at 20, for moving belts 30 to be described. In one embodiment, the drive system 20 includes a plurality of rotatable wheels 22 rotatably supported on the support frame 12. The wheels 22 are rotatably connected to the support frame 12 by a suitable mechanism such as brackets and fasteners. Two of the wheels 22 oppose and are spaced laterally from each other at one end of the support frame 12 and two of the wheels 22 oppose and are spaced laterally from each other at the other end of the support frame 12 for a function to be described. The drive system 20 also includes a motor 24 (FIG. 2) connected to a rotatable shaft 26 on which opposed wheels 22 are rotatably mounted via a transmission 28. The motor 24 is of a variable speed type and allows the speed of belts 30 to be selectively adjusted to a desired consistent speed. Depending upon the type of fasteners processed, the practical belt speed typically ranges from about 30 to about 60 feet/minute, thereby enabling production of 10,000 to more than 160,000 parts/hour by the present invention, depending upon the part, its shape, and size. It should be appreciated that the motor 24 is electrically connected to a source of power such as an apparatus controller 84 to be described.

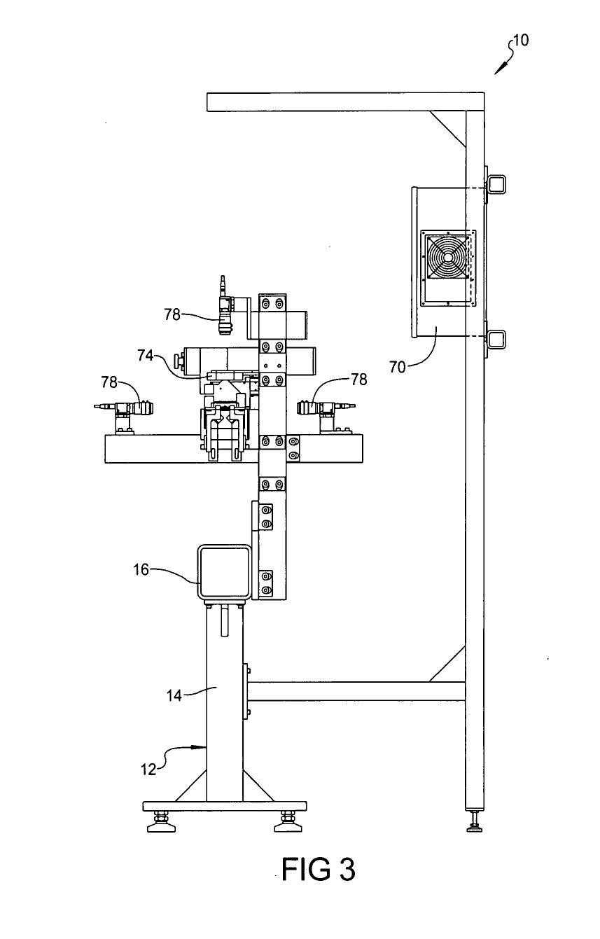

Referring to FIGS. 1 through 3, the conveyor system 18 includes at least one, preferably a plurality of belts 30 disposed about the wheels 22. One belt 30 is disposed about two longitudinally spaced wheels 22 and another belt 30 is disposed about the other two longitudinally spaced wheels 22. The belts 30 are spaced laterally to form an open channel or gap 32 therebetween for moving the objects such as fasteners. Each of the belts 30 has a thickness of approximately 0.002 inches to approximately 0.027 inches. Preferably, each of the belts 30 is a of multiple ply, for example two plys each having a thickness of 0.003 inches for a total thickness of 0.006 inches for each belt 30. The channel 32 has a width of approximately 0.000 inches to approximately 1.50 inches. It should be appreciated that the wheels 22 and belts 30 can be readily adjusted on the conveyor system 18 to accommodate different types and sizes of objects such as fasteners. It should be appreciated that the belts 30 are closed to form a closed-loop and that the gap 32 is narrower at the top of the wheels 22 than at a bottom of the wheels 22 for a function to be described.

The apparatus 10 also includes a feeder system, generally indicated at 34, positioned at one end of the conveyor system 18 to feed the fasteners to the conveyor system 18. The fasteners are orientated and aligned in a uniform manner by the feeder system 34. The feeder system 34 includes a vibratory feed bowl mechanism 35. The feeder system 34 also includes a gravity down track or vibratory in-line track mechanism 36 cooperating with the vibratory feed bowl mechanism 35 and the conveyor system 18. The track mechanism 36 is adjustable from zero degrees (0°) to thirty-five degree (35°) and positioned in a downward slope gravity or vibratory in-line linear type. The track mechanism 36 conveys the fasteners from the vibratory feed bowl mechanism 35 and delivers the fasteners to the conveyor system 18. The feeder system 34 further includes a metering wheel or feed wheel mechanism 38 to meter the fasteners from the track mechanism 36 to engagement with the conveyor system 18. The feed wheel mechanism 38 moves the fasteners and holds the fasteners generally perpendicular to the surface of the belts 30 of the conveyor system 18. In another embodiment, the fasteners could be fed by hand to the conveyor system 18. It should be appreciated that the feed wheel mechanism 38 has independent vertical and horizontal adjustment. It should also be appreciated that a motor (not shown) for the feed wheel mechanism 38 can be adjusted for relatively slow or fast speeds. It should further be appreciated that the feeder system 34 can take many different forms that are well known in the art.

The apparatus 10 includes a powder applicator system, generally indicated at 40, located along the conveyor system 18 to apply a powder coating to the fasteners. The powder applicator system 40 includes a supply bin 42, an actuator 44 that is connected to the apparatus controller to be described, and a powder feeder exit area or nozzle 46. Powdered material is contained in the supply bin 42 and is exited from the supply bin 42 by the actuator 44. The actuator 44 is of a pneumatic type connected to a source of pressurized air (not shown) and to the apparatus controller. The actuator 44 moves the powdered material through the powder feeder nozzle 46 and onto the fasteners passing thereby. It should be appreciated that the actuator 44 provides a continuous deposit of the powdered material through the nozzle 46. It should also be appreciated that the powder applicator system 40 is not shown in FIG. 1 for illustrative purposes.

The apparatus 10 also includes a heating device 48 positioned prior to the powder applicator system 40 along the conveyor system 18. The heating device 48 is of an induction coil type. The heating device 48 is mounted to the support frame 12 by a suitable mechanism such as brackets and fasteners. The objects traverse along the conveyor system 18 and the heating device 48 pre-heats the objects to about 100° F. to about 450° F. prior to the application of any powdered coating materials.

The apparatus 10 also includes a removal assembly, generally indicated at 50, located at the end of the conveyor system 18. The removal assembly 50 includes a deflection chute 52 disposed below one pair of the wheels 28. The deflection chute 52 has a top portion 54 that is generally rectangular in cross-sectional shape. The deflection chute 52 has a bottom portion 56 that is funneled shaped for a function to be described. The deflection chute 52 is connected to the support frame 12 by suitable means such as brackets and fasteners.

The apparatus 10 includes a collector system, generally indicated at 58, disposed below the deflection chute 52. The collector system 58 includes a cart 60. The collector system 58 also includes a first collector 62 for objects that have passed inspection and a second collector 64 for objects that have failed inspection. The first collector 62 and second collector 64 may be buckets and removable from the cart 60.

The apparatus 10 also includes an inspection system, generally indicated at 68, for inspecting the objects such as fasteners to reject or pass the fasteners based on a coating thereon or other attributes of the fasteners. The inspection system 68 cooperates with the apparatus controller 84 to be described for controlling the inspection process. The inspection system 68 includes a camera controller or processor 70 having a microprocessor, memory, and input/output. The camera controller 70 may have a display for images and may permit manual operator setup, programming, and evaluation of the inspected criteria. The inspection system 68 also includes an interactive or human machine interface 72 such as an operator touch screen electrically connected to the camera controller 70. It should be appreciated that the camera controller 70 may be a separate controller or integrated into one controller with the apparatus controller 84. It should also be appreciated that the camera controller 70 may accommodate color or gray scale data acquisition. It should further be appreciated that encoders (not shown) may be provided to cooperate with the inspection system 68 to track the fasteners prior to and/or after the inspection system 68 along the conveyor system 18.

The inspection system 68 further includes at least one, preferably a plurality of light sources 74. The light sources 74 illuminate the fasteners for the inspection system 68. The light sources 74 may be of any suitable type such as light emitting diode (LED) or fluorescent. It should be appreciated that the light sources 74 maintain a constant light emitting power and bath the fasteners with light to reduce the affect of variations in ambient lighting during the inspection process.

The inspection system 68 further includes at least one inspection camera 78 or camera system for inspecting objects or parts such as the fasteners. Preferably, the inspection system 68 includes a plurality of cameras 78 or camera systems that may be designated as primary and secondary inspection cameras depending on the criteria to be inspected. As illustrated, one inspection camera 78 is disposed above the belts 30 and one inspection camera 78 is disposed on each side of the belts 30 and are supported by the frame 12 by a suitable mechanism such as brackets and fasteners. The inspection cameras 78 are electrically connected to the camera controller 70 previously described. Each inspection camera 78 takes a digital image of each object such as a fastener and is sent to the camera controller 70. It should be appreciated that the camera controller 70 receives the image from each inspection camera 78 and determines whether each object passes or fails a predetermined criteria and signals the apparatus controller to position a diverter 80 to be described to the corresponding position. It should also be appreciated that a presence sensor 79 such as a fiber optic through beam sensor or a laser sensor located on the apparatus 10 may be used as a camera trigger with the camera controller 70 and inspection cameras 78. It should further be appreciated that the inspections cameras 78 are conventional and known in the art.

The inspection system 68 also includes a movable diverter 80 disposed between the deflection chute 52 and the collector system 58. The diverter 80 has a generally inverted “V” shape. The diverter 80 is disposed below the bottom portion of the deflection chute 52. As illustrated in FIG. 2, the diverter 80 is shown in a pass position. The diverter 80 is connected to an actuator 82 by a suitable mechanism such as fasteners. The actuator 82 is of a pneumatic type. It should be appreciated that the actuator 82 is connected to a source of air (not shown) and that the apparatus controller 84 controls actuation of the actuator 82 via a signal from the camera controller 70. It should also be appreciated that the actuator 82 moves the diverter 80 laterally to place the diverter 80 between the pass position and the fail position. It should further be appreciated that the diverter 80 has a default position, which is the failed position.

The apparatus 10 includes an apparatus controller 84 for controlling the overall operation of the apparatus 10. The apparatus controller 84 includes a microprocessor, memory, and input/output. The apparatus controller 84 may have a display for images and may permit manual operator setup, programming, and evaluation of the apparatus 10. The apparatus controller 84 is connected to one or more components and/or subsystems of the apparatus 10. The apparatus controller 84 enables the automatic and sequential start-up and shut-down of one or more apparatuses 10 and/or subsystems for such apparatuses 10. It should be appreciated that the apparatus controller 84 for the apparatus 10 is of a programmable logic controller type. It should also be appreciated that the apparatus controller 84 is connected to other components of the apparatus 10 including those not shown or described.

In one embodiment of operation of the apparatus 10, objects or parts such as fasteners are loaded into the feeder 35. The fasteners are fed from the feeder 35 to the track mechanism 36 and feed wheel mechanism 38 and into the gap 32 between the belts 30. Each of the belts 30 holds the fastener in a vertical fashion with the head thereof facing upwardly and the shank disposed below the belts 30. The drive system 20 moves the belts 30 longitudinally, thereby moving the fasteners toward the removal assembly 60. It should be appreciated that the fasteners are conveyed by the belts 30 and moved therealong.

The fasteners pass, in one embodiment, the powder applicator system 40. The powder applicator system 40 applies a powder coating to the fastener. Powdered material contained in the supply bin 42 is exited from the supply bin 42, through the powder feeder nozzle 46, and onto the fastener passing thereby at a predetermined location on the passing fastener. It should be appreciated that the fastener is heated by a source such as an induction heater 48 prior to the powder applicator system 40.

After coating the fasteners, the fasteners pass at least one presence sensor mounted to the support frame 12 in close proximity to the inspection system 68. When the sensor senses the fastener, it sends a signal to the camera controller 70 to indicate that a fastener is present. The encoder is then activated by the apparatus controller 84 to track the fastener along the conveyor system 18. It should be appreciated that the sensor and encoder are conventional and known in the art.

After the presence sensor, the fasteners pass by at least one inspection camera 78 and the inspection camera 78 takes a digital image of each fastener and is sent to the camera controller 70. In the embodiment illustrated, three inspection cameras 78 take a digital image of the fastener as it travels in front of the cameras 78. The camera controller 70 compares the digital image to one stored in memory to determine whether the fastener passes or fails at least one predetermined inspection criteria, for example, whether coating material is present on the fastener, whether the coating material covers a predetermined portion of the fastener, whether dimensional criteria of the fastener has been met, etc.

After inspection and upon reaching the end of the conveyor system 18, the fasteners exit the belts 30 at the middle of the wheels 28 due to the increased width of the gap 32. The fasteners are directed by the deflection chute 52 toward the collector system 58. The camera controller 70, in conjunction with the apparatus controller 84, controls the movement of the diverter 80. If the camera controller 70 determines that the fastener has failed or not passed the inspection criteria, the diverter 80 will be in a default position. The fastener will contact one side of the diverter 80 and fall into the second collector 64. If the camera controller 70 determines that the fastener has passed the inspection criteria, the camera controller 70 will send a signal to the apparatus controller 84, which in turn sends a signal to the actuator 82, to move the diverter 80 laterally to the passed position. The fastener will contact the other side of the diverter 80 and fall into the first collector 62. It should be appreciated that the default position is the failed position.

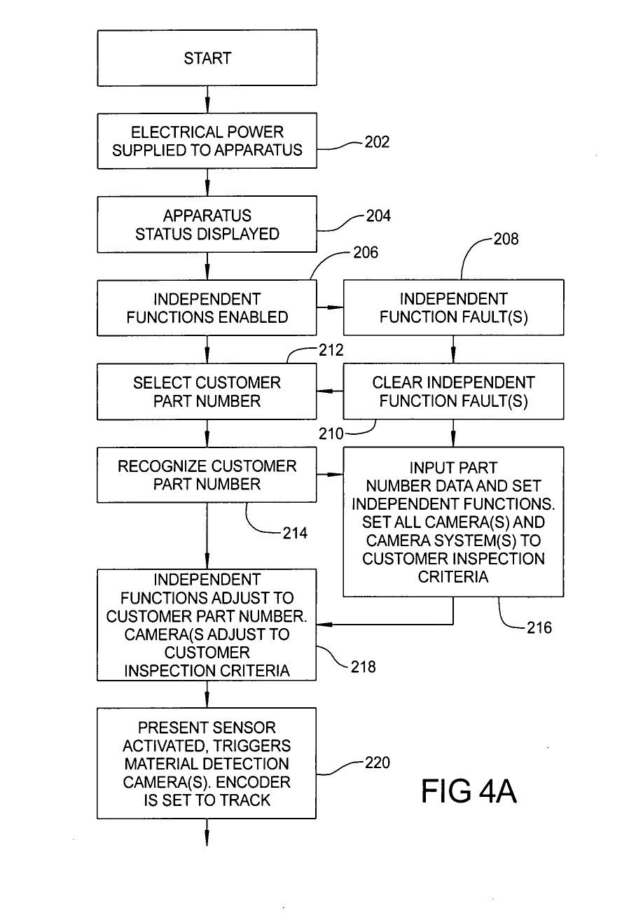

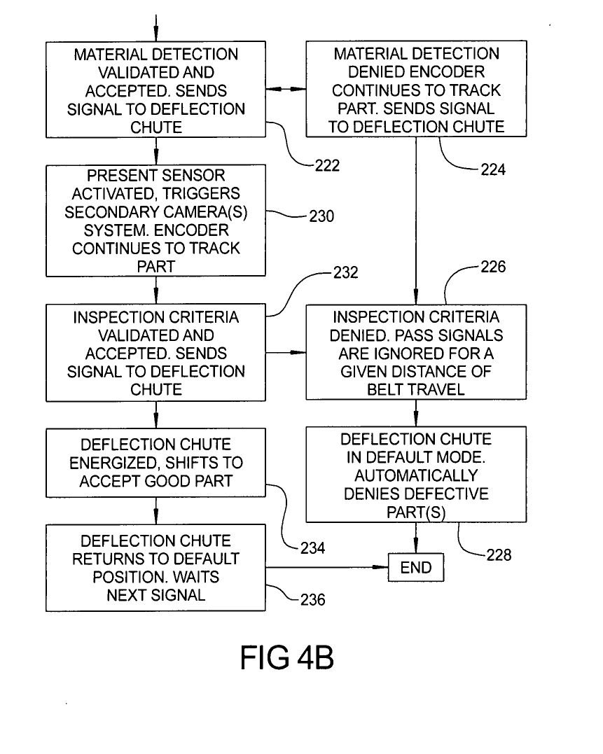

Referring to FIGS. 4A and 4B, a method of inspecting objects or parts such as fasteners with the apparatus 10 is shown. In FIG. 4A, the methodology starts and advances to block 202. In block 202, the methodology includes the step of supplying electrical power to the apparatus 10. Power from a power source (not shown) is supplied to the apparatus controller 84, camera controller 70, human machine interface 72, and inspection cameras 78. It should be appreciated that power is also supplied to other components of the apparatus 10 including those not shown or described.

After block 202, the methodology advance to block 204 and displays the apparatus status screen on the interface 72. The apparatus status screen displays information such as machine status, individual device status, air pressure, belt speed, and induction heater settings. The methodology then advances to block 206 and enables independent functions of the apparatus 10 such as proper belt speed, proper induction heater settings, and proper air pressure. The apparatus controller 84 and interface 72 enable the independent functions of the apparatus 10 by validation of preset variables for processing such as belt speed, air pressure, and induction heater settings. From block 206, the methodology may advance to either block 208 or 212. In block 208, the methodology checks for independent function faults of the apparatus 10. The apparatus controller and interface 72 checks for independent function faults, such as improper air pressure, of the apparatus 10 by monitoring preset variables required for processing. The methodology then advances to block 210 and clears independent function faults of the apparatus 10. The apparatus controller 84 and interface 72 clear the independent function faults of the apparatus 10 by enabling and validating preset variables inputted by the operator of the apparatus 10.

From either block 206 or 210, the methodology advances to block 212 and selects a customer part number. The operator inputs a customer part number into the apparatus controller 84 via the interface 72 by selecting a customer part number from a predetermined list of customer part numbers. From block 212, the methodology advances to block 214 and the functions of the apparatus 10 recognize the customer part number. The apparatus controller 84 recognizes the customer part number and operates the apparatus 10 according to the functions associated with the customer part number. The methodology then advances to either blocks 216 or 218.

In block 216, the methodology inputs a new customer part number and sets independent functions of the apparatus 10 if no customer part number is selected from the predetermined list of customer part numbers. The operator inputs a new customer part number into the apparatus controller 84 via the interface 72 and camera controller 70 and sets independent functions of the apparatus 10 such as coating area, fastener length, thread pitch, and other inspection attributes defined by the customer into the apparatus controller 84 via the interface 72 such that the functions are related or associated with the new customer part number. The methodology also sets all camera systems to the customer's inspection criteria. The operator sets the camera systems to the customer's inspection criteria with the camera controller 70 by selecting from a predetermined list of inspection criteria such as previously described. From block 214 or block 216, the methodology advances to block 218.

In block 218, the methodology adjusts independent functions of the apparatus 10 to the customer part number. The apparatus controller 84 adjusts independent functions of the apparatus 10 such as air pressure, induction heater settings, belt speed, and inspection criteria related to the customer part number. The methodology also adjusts the camera systems to the customer inspection criteria. The camera controller 70 adjusts the camera systems to the customer inspection criteria by recognizing good or acceptable inspection criteria for acceptance and recognizing bad or unacceptable inspection criteria for rejection. The methodology advances to block 220 and activates a part or object presence sensor and triggers one or more inspection cameras 78 for an inspection criteria such as material detection of the coating on the fastener. The presence sensor is activated and sends a signal to the camera controller 70 and a signal to the inspection cameras 78. The methodology also sets an encoder to track the object or part. The camera controller 70 sends a signal to the encoder to track the fastener along the belts 30. After block 220, the methodology advances to block 222 in FIG. 4B.

Referring to FIG. 4B, in block 222, the methodology validates and accepts the material detection. The inspection camera 78 sends a digital image of the fastener passing thereby to the camera controller 70. The camera controller 70 compares the digital image to data stored in memory to validate the material detected on the fastener. If the material detection is valid, the camera controller 70 accepts the inspection criteria. The methodology advances to either block 224 or 230.

In block 224, the methodology denies the inspection criteria and the encoder continues to track the fastener. The camera controller 70 compares the digital image to data stored in memory to validate the inspection criteria of the fastener. If the inspection criteria is not valid, the camera controller 70 rejects the object to be inspected. The methodology also sends a signal to the diverter 80. The camera controller 70 sends a signal to the apparatus controller 84, which, in turn, sends a signal to the actuator 82 to move the diverter 80 within the deflection chute 52 to the failed position if the diverter 80 is currently in the passed position. From block 224, the methodology may return to block 222 or advance to block 226 to be described. It should be appreciated that the failed position is the default position and the diverter 80 will normally be in the failed position and will not be moved unless a passed signal from the camera controller 70 is provided.

In block 226, the methodology denies the inspection criteria. The camera controller 70 compares the digital image to data stored in memory to validate the inspection criteria. If the inspection criteria is not valid, the camera controller 70 sends a signal to the apparatus controller 84 and rejects the inspected object. The methodology also ignores pass signals for a given distance of travel of the belts 30. The camera controller 70 sends a signal to the apparatus controller to ignore pass signals for fasteners for a given distance of travel of the belts 30. The methodology then advances to block 228 and sets the diverter 80 in a failed mode for a failed position and automatically denies or rejects defective fasteners. The methodology then ends. It should be appreciated that the default mode is the failed position for the diverter 80.

From block 222, the methodology advances to block 230 and activates the object presence sensor. The camera controller 70 sends a signal to the apparatus controller 84, which activates the presence sensor. The methodology also triggers secondary inspection cameras 78 and/or camera systems and continues to track the fastener with the encoder. The camera controller 70 sends a signal to the secondary inspection cameras 78 and/or systems and to the encoder to track the fastener. The methodology advances to block 232 and validates and accepts the inspection criteria. The inspection camera 78 sends a digital image of the fastener passing thereby to the camera controller 70. The camera controller 70 compares the digital image to data stored in memory to validate the inspection criteria. If the inspection criteria is valid, the camera controller 70 accepts the inspection criteria. The methodology also sends a signal to the apparatus controller 84 to activate the diverter 80. The camera controller 70 send a signal to the apparatus controller, which in turn sends a signal to the actuator 82, to move the diverter 80 in the pass position if the diverter 80 is currently in the failed or default position. The methodology then advances to either block 226 previously described or block 234 to be described.

From block 232, the methodology advances to block 234, energizes the actuator 82, and positions the diverter 80 to accept good objects or parts. The camera controller 70 sends a signal to the apparatus controller, which energizes the actuator 82 to shift the diverter 80 from the failed position to the pass position to accept fasteners that have passed the inspection criteria. The methodology then advances to block 236 and returns the diverter 80 to the default position, which is the failed position. The methodology waits for the next signal. The methodology then ends.

Accordingly, the present invention is an inspection methodology and apparatus 10 that is designed to inspect a flow of objects or parts in an ordinate and incremental position at a high rate of speed.

The present invention has been described in an illustrative manner. It is to be understood that the terminology, which has been used, is intended to be in the nature of words of description rather than of limitation.

Many modifications and variations of the present invention are possible in light of the above teachings. Therefore, within the scope of the appended claims, the present invention may be practiced other than as specifically described.

What is claimed is:

1. A method for inspecting objects for an inspection criteria thereon, said method comprising the steps of:
providing a conveyor;
receiving a plurality of objects on the conveyor and conveying the objects along the conveyor;
inspecting the objects with an inspection system located along the conveyor against a predetermined inspection criteria;
determining whether to reject or pass the inspected objects; and
removing the passed objects from the conveyor with a removal assembly by actuating the removal assembly to a passed position if the inspected objects are passed, and removing the rejected objects from the conveyor with the removal assembly in a failed position if the inspected objects are rejected.

2. A method as set forth in claim 1 including the step of providing a deflection chute for the removal assembly and disposing the deflection chute below the conveyor.

3. A method as set forth in claim 2 including the step of disposing a collector system below the deflection chute for collecting the passed and failed objects.

4. A method as set forth in claim 3 including the step of providing the collector system with a first collector for objects that have passed inspection and a second collector for objects that have failed inspection.

5. A method as set forth in claim 4 including the step of providing a movable diverter for the inspection system and disposing the movable diverter between the deflection chute and the first collector and the second collector.

6. A method as set forth in claim 5 including the step of providing an actuator to move the diverter.

7. A method as set forth in claim 6 including the step of positioning the diverter in the failed position for a default position.

8. A method as set forth in claim 7 including the step of actuating the actuator and moving the diverter from the failed position to the passed position in response to a passed condition.

9. A method as set forth in claim 1 including the step of providing at least one camera, at least one light source, and a camera controller for the inspection system.

10. A method as set forth in claim 9 including the step of comparing the inspected objects against a predetermined inspection criteria using the camera controller and determining whether to reject or pass the inspected object.

11. A method as set forth in claim 1 including the step of providing the conveyor with a pair of belts being laterally spaced to form a channel therebetween.

12. A method as set forth in claim 11 including the step of providing each of the belts with a thickness of approximately 0.002 inches to approximately 0.027 inches.

13. A method as set forth in claim 11 including the step of forming the channel with a width of approximately 0.000 inches to approximately 1.50 inches.

14. A method as set forth in claim 11 including the step of providing the objects with a diameter of approximately 0.020 inches to approximately 1.50 inches.

15. A method as set forth in claim 11 including the step of providing the objects with a length of approximately 0.030 inches to approximately 10.00 inches.

16. A method of inspecting fasteners for an inspection criteria thereon, said method comprising the steps of:
providing a conveyor;
receiving a plurality of fasteners on the conveyor and conveying the fasteners along the conveyor;
sensing a presence of each of the fasteners along the conveyor with a sensor and triggering at least one inspection camera;
determining whether inspection criteria inspected by the inspection camera on each of the fasteners is acceptable;
validating the inspection criteria if the inspection criteria of each of the fasteners inspected is acceptable and sending a signal to a deflection chute located along the conveyor;
denying the inspection criteria if the inspection criteria of each of the fasteners inspected is not acceptable;
positioning the deflection chute in a default position to automatically deny each of the defective fasteners;
validating inspection criteria if the inspection criteria is acceptable and sending a signal to a deflection chute; and
positioning the deflection chute to an acceptance position to accept the validated fasteners.

17. A method as set forth in claim 16 including the step of placing the deflection chute in a default position and waiting for the next signal.

18. A method as set forth in claim 17 including the step of tracking each of the fasteners along the conveyor and sending a signal to a deflection chute if the inspection criteria is not acceptable.

19. A method as set forth in claim 16 including the step of sensing a presence of each of the fasteners with a sensor and triggering at least one secondary camera.

20. A method as set forth in claim 19 including the step of continuing to track each of the fasteners and denying inspection criteria if the inspection criteria is not acceptable.

21. A method as set forth in claim 20 including the step of ignoring pass signals for a given distance of travel of the conveyor.

22. A method as set forth in claim 16 including the step of selecting a customer part number.

23. A method as set forth in claim 22 including the step of recognizing the selected customer part number and operating the cameras according to customer inspection criteria.

24. A method as set forth in claim 22 including the step of inputting a new customer part number and configuring the cameras to a customer inspection criteria.

25. A method for coating and inspecting objects, said method comprising the steps of:
providing a conveyor;
receiving a plurality of objects on the conveyor and conveying the objects along the conveyor;
applying a coating material to a portion of the objects with at least one applicator located along the conveyor;
inspecting the objects with an inspection system located along the conveyor against a predetermined inspection criteria;
determining whether to reject or pass the inspected objects; and
removing the passed objects from the conveyor with a removal assembly by actuating the removal assembly to a passed position if the inspected objects are passed, and removing the rejected objects from the conveyor with the removal assembly in a failed position if the inspected objects are rejected.

26. A method as set forth in claim 25 including the step of heating the objects to an elevated temperature prior to said step of applying.

27. A method as set forth in claim 26 wherein said step of applying comprise providing a powder applicator system along the conveyor and applying a powder coating to the heated objects.

28. A method as set forth in claim 25 including the step of providing a movable diverter for the inspection system and disposing the movable diverter below the conveyor between a first collector and a second collector.

29. A method as set forth in claim 28 including the step of providing an actuator to move the diverter, positioning the diverter in the failed position for a default position, and moving the diverter with the actuator from the failed position to the passed position in response to a passed condition.

30. A method as set forth in claim 25 wherein said step of inspecting includes providing at least one camera, a light source, and a camera controller communicating with the at least one camera.

31. A method as set forth in claim 30 wherein said step of inspecting includes comparing the inspected objects against a predetermined inspection criteria with the camera controller and determining whether to reject or pass the inspected objects.

32. A method as set forth in claim 25 including the step of providing the conveyor with a pair of belts being laterally spaced to form a channel therebetween.

33. A method as set forth in claim 32 including the step of providing each of the belts with a thickness of approximately 0.002 inches to approximately 0.027 inches.

34. A method as set forth in claim 32 including the step of forming the channel with a width of approximately 0.000 inches to approximately 1.50 inches.

35. A method as set forth in claim 32 including the step of providing the objects with a diameter of approximately 0.020 millimeter to approximately 1.50 inches.

36. A method as set forth in claim 32 including the step of providing the objects with a length of approximately 0.030 inches to approximately 10.0 inches.
